(19) United States
(12) Patent Application Publication
(10) Pub. No.: US 2023/0343554 A1
(43) Pub. Date: Oct. 26, 2023

(54) Methods To Provide Anisotropic Etching Of Metal Hard Masks Using A Radio Frequency Modulated Pulsed Plasma Scheme

(71) Applicant: Tokyo Electron Limited, Tokyo (JP)

(72) Inventors: Ya-Ming Chen, Austin, TX (US); Eric Chih-Fang Liu, Albany, NY (US); Shihsheng Chang, Albany, NY (US); Emilia Hirsch, Albany, NY (US); Na Young Bae, Albany, NY (US); Angelique Raley, Albany, NY (US)

(21) Appl. No.: 17/725,040

(22) Filed: Apr. 20, 2022

(51) Int. Cl. H01J 37/32; H01L 21/311

(52) U.S. Cl. CPC H01J 37/32146; H01J 37/321; H01J 37/32165; H01J 37/3244; H01J 37/32422; H01L 21/31116; H01J 2237/334

(57) ABSTRACT

The present disclosure provides various embodiments of plasma processing systems, plasma etch process steps and methods for etching features (e.g., contact holes, vias, trenches, etc.) within one or more material layers formed on a substrate, where such material layers include but are not limited to, a metal hard mask layer formed above a dielectric layer. The embodiments disclosed herein reduce or eliminate problems, such as undercutting of the metal hard mask layer and/or recess into the underlying dielectric layer, that occur during conventional continuous wave plasma etch processes by using a pulsed plasma to etch the features within the metal hard mask layer. A radio frequency (RF) modulated pulsed plasma scheme is disclosed herein to improve anisotropic etching of the features within the metal hard mask layer.

### BACKGROUND

The present disclosure relates to the processing of substrates. In particular, it provides plasma processing systems, plasma processes and methods for etching metal hard mask materials with a pulsed plasma.

The use of plasma processing systems for the processing of substrates (such as semiconductor wafers) is well known. A variety of plasma processing systems have been used for processing substrates, including inductively coupled plasma (ICP) processing systems, capacitively coupled plasma (CCP) processing systems and other plasma processing systems. Plasma processing systems generate plasma by supplying high frequency electrical power to process gases injected into a plasma process chamber to ionize the gases in the plasma process chamber. For example, high frequency source power may be supplied to a radio frequency (RF) antenna (in an ICP processing system) or an upper electrode (in a CCP processing system) to generate an electric field, which dissociates and converts the process gases delivered to the process chamber into a plasma. The plasma generated within the process chamber contains positive and negative ions, electrons and neutral radical species, which can be used for processing a target substrate in various types of treatments such as, but not limited to, plasma ashing, etching, deposition and/or sputtering. For example, ions accelerated from the plasma may bombard a surface of the target substrate to etch features (such as, e.g., contacts, vias, trenches, etc.) within one or more material layers of the target substrate.

The source power is typically applied at relatively high frequencies (e.g., 10-100 MHz) and is used to generate the plasma and control the density of the plasma generated within the process chamber. In addition to the source power, a separate bias power may be supplied to a lower electrode of the plasma processing system. The bias power is typically applied at lower frequencies (e.g., 100's of kHz to 10 MHz or more) and is used to control the ion bombardment energy. As known in the art, the source power and the bias power may be applied continuously to generate continuous wave (CW) plasmas, or may be pulsed to generate pulsed plasmas within the process chamber.

As known in the art, hard mask layers are often utilized to etch features within one or more material layers of a target substrate. For example, metallic materials (such as titanium nitride, TiN) are widely used as hard mask materials for etching low-k dielectric layers in back end of line (BEOL) process flows. As device dimensions continue to shrink, tungsten-based and other metal-based hard mask materials are emerging as alternative hard mask materials for etching low-k dielectric materials to achieve better line performance, hard mask-to-low-k selectivity and metal-free etch profiles.

Etching of titanium-based and tungsten-based hard mask materials using chlorine-containing and fluorine-containing plasmas has been widely studied. One conventional plasma etch process for etching titanium-based and tungsten-based hard mask materials uses a CW plasma to etch features within the hard mask materials. However, anisotropic etch profiles cannot be achieved in such processes without significant undercutting of the hard mask material and recess into the underlying layer. This is undesirable, as it results in necking and bowing of the underlying layer.

### SUMMARY

The present disclosure provides various embodiments of plasma processing systems, plasma etch process steps and methods for etching features (e.g., contact holes, vias, trenches, etc.) within one or more material layers formed on a substrate, where such material layers include but are not limited to, a metal hard mask layer formed above a dielectric layer. The embodiments disclosed herein reduce or eliminate problems, such as undercutting of the metal hard mask layer and/or recess into the underlying dielectric layer, that occur during conventional CW plasma etch processes by using a pulsed plasma to etch the features within the metal hard mask layer. As known in the art, a pulsed plasma may be generated within a process chamber by pulsing the source power and the bias power supplied to the plasma processing system, while process gases are injected into the process chamber. As described in more detail below, pulsed plasmas enable positive ions and negative ions to be alternately extracted from the pulsed plasma, and accelerated towards the substrate to, therefore, provide a more anisotropic etch profile of features etched within the material layers formed on the substrate.

In preferred embodiments, a pulsed plasma is generated by modulating a source power pulse and a bias power pulse with a radio frequency (RF) modulation frequency. More specifically, an RF modulated source power pulse may be applied to generate a pulsed plasma within the process chamber during an active glow phase of the pulsed plasma (when the source power is turned “on”). After the RF modulated source power is turned “off,” an RF modulated bias power pulse may be applied, after a predetermined time delay, during a late afterglow phase of the pulsed plasma. The predetermined time delay between the end of the active glow phase and the application of the RF modulated bias power pulse in the late afterglow phase enables the pulsed plasma generated within the process chamber to fully quench and modulates the ion flux of the generated plasma. Applying the RF modulated bias power pulse during the late afterglow phase improves anisotropic etching by enabling highly directional positive and negative ions to be extracted from the pulsed plasma and directed towards the substrate.

For example, combining RF modulated source pulsing with RF modulated bias pulsing in the late afterglow phase of the pulsed plasma results in acceleration of positive ions (during the active glow phase) and alternating acceleration of positive and negative ions (during the afterglow phase) out of the pulsed plasma onto the substrate. Since the flux of the ions extracted from the pulse plasma is anisotropic (substantially perpendicular to the substrate), and since the energy of the ions can be tuned by controlling the bias, the positive and negative ions extracted from the pulsed plasma are utilized herein to provide highly anisotropic etch profiles of the features etched within the material layers formed on the substrate.

In some embodiments, the techniques described herein may be utilized for etching metal hard mask layers, such as but not limited to, titanium-based, tungsten-based, ruthenium-based and other metal-based hard mask materials. It is recognized that metal hard mask materials are merely one example of materials that may be etched using the techniques described herein. One skilled in the art would understand how other material layers may also be etched using the techniques described herein.

According to a first embodiment, a method is provided herein for etching features within a material layer formed on a substrate in accordance with the present disclosure. The method may include providing the substrate within a process chamber of a plasma processing system, supplying one or more process gases to the process chamber, and supplying a plurality of source power pulses to the plasma processing system at a first frequency, while the one or more process gases are supplied to the process chamber, to generate a pulsed plasma within the process chamber. In some embodiments, said supplying one or more process gases to the process chamber may include supplying at least one halogen-containing gas to the process chamber.

The method may also include supplying a plurality of bias power pulses to the plasma processing system at a second frequency, which is less than the first frequency, and modulating the plurality of bias power pulses at a modulation frequency to repeatedly change a polarity of the bias power during each bias power pulse. In addition, the method may include utilizing the pulsed plasma to etch the features within the material layer formed on the substrate. By modulating the plurality of bias power pulses, the method described in the first embodiment provides anisotropic etching of the features within the material layer by alternately extracting positive ions and negative ions from the pulsed plasma and accelerating the alternately extracted positive ions and negative ions towards the substrate to etch the features within the material layer. In some embodiments, the alternately extracted positive ions and negative ions may bombard a surface of the substrate at an angle of incidence that is within 10 degrees of perpendicular to the substrate.

The method described in the first embodiment may be utilized within a wide variety of plasma processing systems. In some embodiments, the method may be utilized within an inductively coupled plasma (ICP) processing system. In such embodiments, said supplying the plurality of source power pulses may include supplying the plurality of source power pulses to a radio frequency (RF) antenna included within an ICP processing system to generate an inductive electric field, which converts the one or more process gases supplied to the process chamber into the pulsed plasma. In addition, said supplying the plurality of bias power pulses may include supplying the plurality of bias power pulses to a base electrode included within the ICP processing system.

In some embodiments, the plurality of source power pulses may be supplied at a source power level ranging between 100 W and 300 W, the first frequency may range between 13 MHz to 60 MHz. In some embodiments, the method may further include modulating the plurality of source power pulses at the modulation frequency to repeatedly change a polarity of the source power during each source power pulse. In such embodiments, the modulation frequency may range between 100 Hz to 10 kHz. In one example embodiment, 300 W source power pulses may be supplied at a first frequency of 27 MHz, and the source power pulses may be modulated at a modulation frequency of 10 kHz.

In some embodiments, the plurality of bias power pulses may be supplied at a bias power level ranging between 100 W and 500 W, the second frequency may range between 1 MHz to 13 MHz, and the modulation frequency may range between 100 Hz to 10 kHz. In one example embodiment, 500 W bias power pulses may be supplied at a second frequency of 13 MHz, and the bias power pulses may be modulated at a modulation frequency of 10 kHz.

In some embodiments, the method described in the first embodiment may further include providing a predetermined time delay between each source power pulse supplied to the RF antenna and each bias power pulse supplied to the base electrode. The predetermined time delay enables the pulsed plasma generated within the process chamber to fully quench before each bias power pulse is supplied to the base electrode. In some embodiments, the predetermined time delay may range between 15-30 μsec. In one example implementation, the predetermined time delay may be 20 μsec.

According to a second embodiment, a method to provide anisotropic etching of features within a hard mask layer formed on a substrate is provided in accordance with the present disclosure. The method may generally include providing the substrate within a process chamber of a plasma processing system, generating a pulsed plasma within the process chamber and utilizing the pulsed plasma generated within the process chamber to etch the features within the hard mask layer formed on the substrate.

In the second embodiment, the method may generate a pulsed plasma within the process chamber by: (a) supplying one or more process gases to the process chamber; (b) supplying a source power to the plasma processing system at a first frequency to generate an electric field, which converts the one or more process gases into the pulsed plasma, wherein during each pulse period of the first frequency, the source power is turned on during an active glow phase and turned off during an afterglow phase of the pulsed plasma; (c) supplying a bias power to the plasma processing system during each afterglow phase of the pulsed plasma; and (d) modulating the bias power at a modulation frequency to repeatedly change a polarity of the bias power supplied during each afterglow phase of the pulsed plasma. Modulating the bias power in step (d) alternately extracts positive ions and negative ions from the pulsed plasma during the afterglow phase of the pulsed plasma, and provides anisotropic etching of the features within the hard mask layer by accelerating the alternately extracted positive ions and negative ions towards the substrate to etch the features within the hard mask layer. In some embodiments, the alternately extracted positive ions and negative ions may bombard a surface of the substrate at an angle of incidence that is within 10 degrees of perpendicular to the substrate.

In some embodiments, said supplying the bias power in step (c) may include turning the bias power on a predetermined time delay after the source power is turned off during each afterglow phase of the pulsed plasma. As noted above, the predetermined time delay enables the pulsed plasma generated within the process chamber to fully quench before the bias power pulse is turned on.

In some embodiments, the method described in the second embodiment may further include modulating the source power at the modulation frequency to repeatedly change a polarity of the source power supplied during each active glow phase of the pulsed plasma. Modulating the source power extracts positive ions from the pulsed plasma during the active glow phase of the pulsed plasma, and improves anisotropic etching of the features within the hard mask layer by accelerating the positive ions extracted during the active glow phase towards the substrate to etch the features within the hard mask layer. The positive ions extracted from the pulsed plasma during the active glow phase of the pulsed plasma may also bombard the surface of the substrate at an angle of incidence that is within 10 degrees of perpendicular to the substrate.

Like the previous embodiment, the method described in the second embodiment may be utilized within a wide variety of plasma processing systems. In some embodiments, the method may be utilized within an inductively coupled plasma (ICP) processing system. In such embodiments, said supplying the source power may include supplying the source power pulses to a radio frequency (RF) antenna included within an ICP processing system to generate an inductive electric field, which converts the one or more process gases supplied to the process chamber into the pulsed plasma. In addition, said supplying the bias power may include supplying the bias power to a base electrode included within the ICP processing system at a second frequency range, which is less than the first frequency range. In some embodiments, the one or more process gases supplied to the process chamber may include at least one halogen-containing gas.

In some embodiments, the source power may be supplied at a source power level ranging between 100 W and 300 W, the first frequency may range between 13 MHz to 60 MHz. In some embodiments, the method may further include modulating the source power at the modulation frequency to repeatedly change a polarity of the source power supplied during each active glow phase of the pulsed plasma. In such embodiments, the modulation frequency may range between 100 Hz to 10 kHz. In one example embodiment, 300 W of source power may be supplied at a first frequency of 27 MHz and modulated at a modulation frequency of 10 kHz.

In some embodiments, the bias power may be supplied at a bias power level ranging between 100 W and 500 W, the second frequency may range between 1 MHz to 13 MHz, and the modulation frequency may range between 100 Hz to 10 kHz. In one example embodiment, 500 W of bias power may be supplied at a second frequency of 13 MHz and modulated at a modulation frequency of 10 kHz.

The methods described in the first and second embodiments may be utilized for etching a wide variety of material layers. In some embodiments, the methods described herein may be utilized for etching features within a metal hard mask layer overlying a dielectric layer. For example, the metal hard mask layer may include titanium, tungsten or ruthenium hard mask materials, such as but not limited to, titanium nitride (TiN), tungsten carbide (WC), tungsten nitride (WN), tungsten silicide (WSix), ruthenium nitride (RuN), ruthenium Silicide (RuSi), etc. The dielectric layer may include a low-k dielectric material, such as but not limited to, SiOCH or SiCOOH. Other metal hard mask materials and dielectric materials may also be utilized in the methods described herein.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 is a simplified block diagram of an example plasma processing system that utilizes pulsed plasma techniques for etching material layers on a substrate.

FIG. 2 is a timing diagram illustrating one pulse period of a radio frequency (RF) modulated pulsed plasma scheme in accordance with the present disclosure.

FIG. 3 illustrates one embodiment of an improved plasma etch process that may be used to etch features within a metal hard mask layer using the RF modulated pulsed plasma scheme shown in FIG. 2.

FIG. 4 illustrates an example inductively coupled plasma (ICP) processing system that may be utilized to perform the techniques described herein.

FIG. 5 is a flowchart diagram illustrating one embodiment of a method that utilizes the techniques described herein to etch features within a material layer formed on a substrate.

FIG. 6 is a flowchart diagram illustrating another embodiment of a method that utilizes the techniques described herein to provide anisotropic etching of features etched within a hard mask layer formed on a substrate.

### DETAILED DESCRIPTION

The present disclosure provides various embodiments of plasma processing systems, plasma etch process steps and methods for etching features (e.g., contact holes, vias, trenches, etc.) within one or more material layers formed on a substrate, where such material layers include but are not limited to, a metal hard mask layer formed above a dielectric layer. The embodiments disclosed herein reduce or eliminate problems, such as undercutting of the metal hard mask layer and/or recess into the underlying dielectric layer, that occur during conventional CW plasma etch processes by using a pulsed plasma to etch the features within the metal hard mask layer. As known in the art, a pulsed plasma may be generated within a process chamber by pulsing the source power and the bias power supplied to the plasma processing system, while process gases are injected into the process chamber. As described in more detail below, pulsed plasmas enable positive ions and negative ions to be alternately extracted from the pulsed plasma, and accelerated towards the substrate to, therefore, provide a more anisotropic etch profile of features etched within the material layers formed on the substrate.

In preferred embodiments, a pulsed plasma is generated by modulating a source power pulse and a bias power pulse with a radio frequency (RF) modulation frequency. More specifically, an RF modulated source power pulse may be applied to generate a pulsed plasma within the process chamber during an active glow phase of the pulsed plasma (when the source power is turned “on”). After the RF modulated source power is turned “off,” an RF modulated bias power pulse may be applied, after a predetermined time delay, during a late afterglow phase of the pulsed plasma. The predetermined time delay between the end of the active glow phase and the application of the RF modulated bias power pulse in the late afterglow phase enables the pulsed plasma generated within the process chamber to fully quench and modulates the ion flux of the generated plasma. Applying the RF modulated bias power pulse during the late afterglow phase improves anisotropic etching by enabling highly directional positive and negative ions to be extracted from the pulsed plasma and directed towards the substrate.

For example, combining RF modulated source pulsing with RF modulated bias pulsing in the late afterglow phase of the pulsed plasma results in acceleration of positive ions (during the active glow phase) and alternating acceleration of positive and negative ions (during the afterglow phase) out of the pulsed plasma onto the substrate. Since the flux of the ions extracted from the pulsed plasma is anisotropic (substantially perpendicular to the substrate), and since the energy of the ions can be tuned by controlling the bias, the positive and negative ions extracted from the pulsed plasma are utilized herein to provide highly anisotropic etch profiles of the features etched within the material layers formed on the substrate.

In some embodiments, the techniques described herein may be utilized for etching metal hard mask layers, such as but not limited to, titanium-based, tungsten-based, ruthenium-based and other metal-based hard mask materials. It is recognized that metal hard mask materials are merely one example of materials that may be etched using the techniques described herein. One skilled in the art would understand how other material layers may also be etched using the techniques described herein.

In some embodiments, the techniques described herein may be utilized within an inductively coupled plasma (ICP) processing system. An ICP system may be preferred, in some embodiments, for its ability to provide independent control of ion energy and flux and to operate at low pressure (e.g., 10-30 mTorr). It will be recognized by those skilled in the art, however, that the techniques described herein may be utilized with any of a wide variety of plasma processing systems, including an ICP processing system, a CCP processing system, a microwave plasma processing system, a Radial Line Slot Antenna (RLSA™) microwave plasma processing system, an electron cyclotron resonance (ECR) plasma processing system, or other type of processing system or combination of systems.

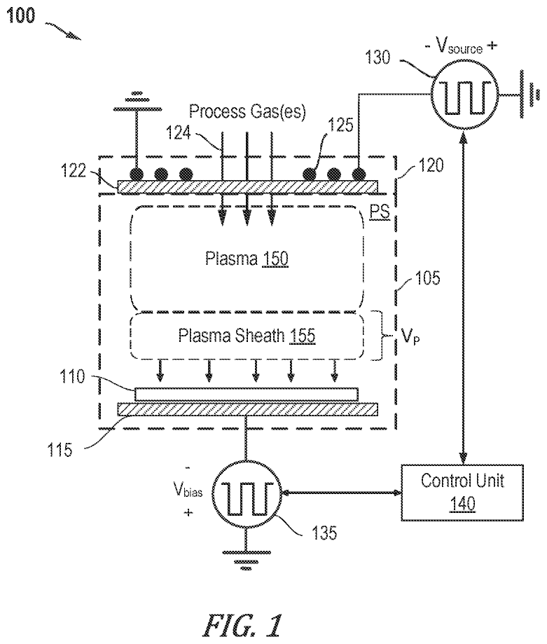

FIG. 1 provides one example embodiment for a plasma processing system 100 that can be used with respect to the disclosed techniques and is provided only for illustrative purposes. The plasma processing system 100 shown in FIG. 1 is an ICP processing system. The plasma processing system 100 shown in FIG. 1 can be used for a wide variety of operations including, but not limited to, plasma ashing, etching, deposition and/or sputtering. The structure of an ICP plasma processing system 100 is well known, and the particular structure provided herein is simplified for illustrative purposes. It will be recognized that different and/or additional plasma process systems may be implemented while still taking advantage of the techniques described herein.

Looking in more detail to FIG. 1, the plasma processing system 100 includes a process chamber 105, which defines a processing vessel providing a process space (PS) for plasma generation. As is known in the art, the process chamber 105 may be a pressure controlled chamber. A substrate 110 (e.g., a semiconductor wafer) may be held on a susceptor 115 within a lower central area of the process chamber 105. The susceptor 115 can serve as a mounting table on which, for example, a substrate 110 to be processed can be mounted. The susceptor 115 may include a base electrode (not shown in FIG. 1).

The plasma processing system 100 shown in FIG. 1 is partitioned by a window 122, which separates the process chamber 105 from an antenna chamber 120 arranged above the process chamber. The window 122 forms a ceiling of the process chamber 105 and can be implemented with a dielectric material, such as quartz, or a conductive material, such as metal. A gas supply line 124 communicates with gas injection openings (not shown in FIG. 1) provided within the window 122 for injecting one or more process gases into the process space (PS). Example process gases that may be injected into the process space include, but are not limited to, halogen-containing gases, oxygen-containing gases, fluorocarbons, inert gases and other process gases. The gas supply line 124 defines a flow path through the ceiling of the process chamber 105 and is connected to a process gas supply system (not shown in FIG. 1), which may include a processing gas supply source, a valve system and corresponding components. In this manner, process gas(es) can be injected into the process space (PS) during plasma processing.

A radio frequency (RF) antenna 125 is provided within the antenna chamber 120 and disposed above the window 122. During plasma processing, source power (V_{source}) can be supplied from a first RF power source 130 to the RF antenna 125 for generating an inductive electric field, which disassociates and converts the process gas(es) supplied to the process chamber 105 into a plasma 150. The source power (V_{source}) may be supplied from the first RF power source 130 to the RF antenna 125 at a high frequency ranging between, e.g., 13 MHz to 60 MHz. In one embodiment, the source power (V_{source}) may be supplied at a first frequency of, e.g., 27 MHz (or another frequency). An impedance matching unit (not shown in FIG. 1) can be connected to the first RF power source 130 to match the impedance of the RF antenna 125 to the first RF power source 130.

As shown in FIG. 1, a second RF power source 135 may be connected to the susceptor 115 via another impedance matching unit (not shown in FIG. 1) for supplying a bias power (V_{bias}) to the base electrode during plasma processing. The bias power (V_{bias}) supplied from the second RF power source 135 to the base electrode may be supplied at lower frequency ranging between, e.g., 1 MHz to 13 MHz. In one embodiment, the bias power (V_{bias}) may be supplied at a second frequency of, e.g., 13 MHz (or another frequency). Applying a bias power (V_{bias}) causes ions, in the plasma 150 generated within the process chamber 105, to be attracted to the substrate 110.

Components of the plasma processing system 100 can be connected to, and controlled by, a control unit 140 that in turn can be connected to a corresponding memory storage unit (not shown in FIG. 1) and user interface (not shown in FIG. 1). Various plasma processing operations can be executed via the user interface, and various plasma processing recipes and operations can be stored in the memory storage unit. Accordingly, a given substrate 110 can be processed within the process chamber 105 with various microfabrication techniques. It will be recognized that control unit 140 may be coupled to various components of the plasma processing system 100 to receive inputs from, and provide outputs to, the components.

In some embodiments, the control unit 140 may be coupled to: the first RF power source 130 to control the source power (V_{source}) supplied to the RF antenna 125, the second RF power source 135 to control the bias power (V_{bias}) supplied to the substrate electrode, the process gas supply system to control the process gas(es) supplied to the process chamber 105, etc., during plasma processing. Example operational ranges are provided above for the source and bias power. However, different operational ranges can also be used depending on the type of plasma processing system, the material being processed within the plasma processing system and the type of treatments (e.g., etching, deposition, sputtering, etc.) performed therein.

The control unit 140 can be implemented in a wide variety of manners. In one example, the control unit 140 may be a computer. In another example, the control unit 140 may include one or more programmable integrated circuits that are programmed to provide the functionality described herein. For example, one or more processors (e.g., a microprocessor, microcontroller, central processing unit, etc.), programmable logic devices (e.g., complex programmable logic device (CPLD), field programmable gate array (FPGA), etc.), and/or other programmable integrated circuits can be programmed with software or other programming instructions to implement the functionality of a particular plasma process recipe. It is further noted that the software or other programming instructions executed by the programmable integrated circuits can be stored in one or more non-transitory computer-readable mediums (e.g., memory storage devices, FLASH memory, dynamic random access (DRAM) memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

In operation, the plasma processing system 100 shown in FIG. 1 generates a plasma 150 in the process chamber 105 by applying source power (V_{source}) from the first RF power source 130 to the RF antenna 125 and bias power (V_{bias}) from the second RF power source 135 to the substrate electrode while one or more process gases are supplied to the process chamber 105. The application of power generates a high-frequency inductive electric field, which dissociates and converts the process gas(es) delivered to the process chamber 105 into a plasma 150. The generated plasma 150 can be used for processing a target substrate (such as substrate 110) in various types of treatments such as, but not limited to, plasma ashing, etching, deposition and/or sputtering.

In one embodiment, electronegative process gases, such as halogen-containing gases, fluorocarbons and oxygen-containing gases, may be delivered to the process chamber 105 and converted into an electronegative gas plasma. As known in the art, electronegative gas plasmas tend to stratify into separate regions of positive and negative ions. Negative ions pile up in the central region of the plasma to form an electronegative core, which is surrounded by a region devoid of negative ions (i.e., an electropositive periphery), followed by a plasma sheath 155 containing only positive ions and electrons.

As noted above, the example plasma processing system 100 shown in FIG. 1 utilizes two RF sources. In some embodiments, the first RF power source 130 provides source power (V_{source}) at relatively high frequencies to convert the process gas(es) delivered to the process chamber 105 into the plasma 150 and to control the plasma density, while the second RF power source 135 provides bias power (V_{bias}) at lower frequencies to control ion bombardment energy. As known in the art, the source power (V_{source}) and the bias power (V_{bias}) may be applied continuously to generate continuous wave (CW) plasmas, or may be pulsed to generate pulsed plasmas within the process chamber 105. Pulsed plasmas can be generated by modulating the source power and/or the bias power in time, amplitude and/or phase.

A plasma 150 is an ionized gas phase substance that consists of positive and negative ions, electrons and neutral atoms/molecules that grossly maintain charge neutrality. One important property of plasmas, known as quasi-neutrality, is that the density of the negative species (electrons and negative ions) in the plasma is equal to the density of the positive species (positive ions) in the plasma. Although a majority of the plasma 150 generated within the process chamber 105 maintains charge neutrality, voltage potentials (VP) can develop across boundary regions of the plasma 150, resulting in a positively charged plasma sheath 155.

When CW plasmas are generated within the process chamber 105, the plasma sheath 155 has only positive ions and neutral radical species, and thus, an overall positive charge. Negative ions cannot enter the plasma sheath 155 when CW plasmas are generated, since the negative ion energy is far less than the voltage potential (VP) of the sheath. Thus, when CW plasmas are generated, the plasma sheath 155 ensures that the plasma 150 remains quasi-neutral by trapping low energy electrons and negative ions within the plasma 150 and accelerating positive ions towards the substrate 110 in a direction substantially perpendicular to the substrate 110. Since neutral radical species have no directionality, and only positive ions are directed vertically to the substrate 110, CW plasmas cannot be used to provide anisotropic etch profiles of features etched within material layers formed on the substrate 110.

To overcome the disadvantages of conventional CW plasma etch processes, the present disclosure provides various embodiments of plasma processing systems, plasma etch process steps and methods, which utilize a pulsed plasma for etching features (such as, e.g., contact holes, vias, trenches, etc.) within one or more material layers formed on the substrate 110. As described in more detail below, a pulsed plasma enables both positive ions and negative ions to be extracted from the pulsed plasma, and accelerated towards the substrate 110 in a direction substantially perpendicular to the substrate 110, to provide a more anisotropic etch profile of features etched within the material layers formed on the substrate 110. Although the embodiments disclosed herein may be used for etching a wide variety of material layers, they may be particularly well-suited for etching metal hard mask materials formed above a dielectric layer. When utilized for such purpose, the embodiments disclosed herein may reduce or eliminate problems, such as undercutting of the metal hard mask layer and/or recess into the underlying dielectric layer, that occur during conventional CW plasma etch processes.

To generate a pulsed plasma 150 within the process chamber 105, the source power (V_{source}) and the bias power (V_{bias}) are “pulsed” or modulated in time. Within each pulse, the source power (V_{source}) is turned “on” for a time duration (τₒₙ) and turned “off” for a time duration (τ_{off}). The pulse period is defined as τₚ=τₒₙ+τ_{off} and the duty cycle is defined as D=τₒₙ/τₚ (i.e., fraction of the cycle that the source power is “on”). When a pulsed plasma 150 is generated within the process chamber 105, the duration of the source power “on” time (τₒₙ) is referred to as the “active glow” phase, while the duration of the source power “off” time (τ_{off}) is referred to as the “afterglow” phase of the pulsed plasma.

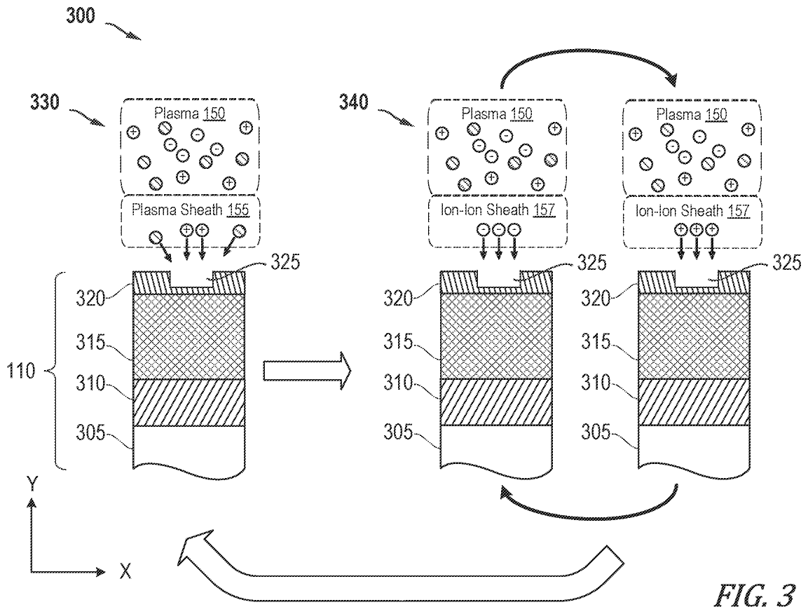

When a pulsed plasma 150 is generated within the process chamber 105 by applying a source power (V_{source}) to the RF antenna 125, positive ions are extracted from the plasma sheath 155 and accelerated towards the substrate 110, as shown in FIG. 3. Although negative ions are trapped in CW plasmas, negative ions can be extracted from the pulsed plasma 150 when a bias voltage (V_{bias}) pulse is applied during the late afterglow phase of plasma. This is because the electron density plummets in the early afterglow phase, forming an ion-ion plasma. By applying a bias to the substrate, negative ions can be extracted from the pulsed plasma 150 into the ion-ion sheath 157 and accelerate towards the substrate 110, as shown in FIG. 3. Combining source pulsing with bias pulsing in the late afterglow phase can, therefore, result in acceleration of positive ions out of the plasma sheath 155 and alternating acceleration of positive ions and negative ions out of the ion-ion sheath 157 and onto the substrate 110. Since the flux of the bombarding ions is anisotropic (substantially perpendicular to the substrate 110 and parallel to the electric field), and since the energy of the ions can be tuned by controlling the bias, the positive ions extracted from the plasma sheath 155 (during the active glow phase) and the positive and negative ions alternately extracted from the ion-ion sheath 157 (during the late afterglow phase) can be utilized to provide anisotropic etch profiles of features etched within material layers formed on the substrate 110.

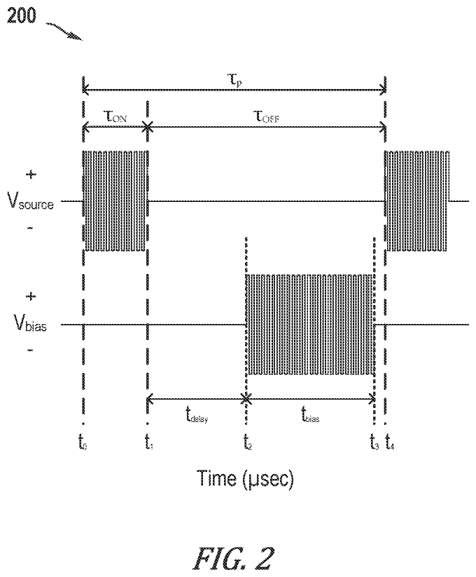

FIG. 2 illustrates one example of a pulsed plasma scheme 200 that may be used to generate a pulsed plasma 150 in accordance with preferred embodiments of the present disclosure. More specifically, FIG. 2 illustrates one pulse period (τₚ) of a pulsed plasma scheme 200 in which an RF modulated source power (V_{source}) pulse is applied during the active glow phase (τₒₙ) and an RF modulated bias power (V_{bias}) pulse is applied during the afterglow phase (τ_{off}) of the pulsed plasma generated within the process chamber 105. In the pulsed plasma scheme 200 shown in FIG. 2, the source power (V_{source}) pulse and the bias power (V_{bias}) pulse are modulated with a modulation frequency (ranging, e.g., between 100 Hz to 10 kHz) and each pulse is applied for a given amount of time. Although example pulse durations are shown in FIG. 2, the duration of the RF modulated source power (V_{source}) pulse and the duration of the RF modulated bias power (V_{bias}) pulse may each range between 10-50% of the pulse period (τₚ).

In the example pulsed plasma scheme 200 shown in FIG. 2, an RF modulated source power (V_{source}) pulse applied to the RF antenna 125 is turned “on” (τₒₙ) that ranges (τₒₙ) between time to (when the source power is turned “on”) and the time t₁ (when the source power is turned “off”). In some embodiments, the RF modulated source power (V_{source}) pulse may be turned “on” (τₒₙ) for approximately 10-30 μsec to generate a pulsed plasma 150 within the process chamber 105. In one example implementation, a 300 W RF modulated source power (V_{source}) pulse may be applied for approximately 20 μsec in the example embodiment shown in FIG. 2. However, one skilled in the art would understand how alternative source power levels and/or pulse durations may also be utilized to generate the pulsed plasma 150.

After the RF modulated source power (V_{source}) pulse is turned “off” at time t₁, an RF modulated bias power (V_{bias}) pulse may be applied to the base electrode to tune the flux of the ions extracted from the pulsed plasma 150. As shown in FIG. 2, the RF modulated bias power (V_{bias}) pulse is applied during the late afterglow phase (τ_{off}) of the pulsed plasma 150 after a predetermined time delay (t_{delay}). The time delay (t_{delay}) between the time t₁ (when the source power is turned “off”) and the time t₂ (when the bias power is turned “on”) is the duration of time needed for the pulsed plasma 150 generated within the process chamber 105 to fully quench. This time delay, or quenching time, may range between approximately 15-30 μsec, depending on the size of the process chamber 105 and the chemistry used to generate the plasma. In one example implementation, a time delay (t_{delay}) of approximately 20 μsec may be sufficient to fully quench the pulsed plasma 150 generated within the process chamber 105.

As shown in FIG. 2, the RF modulated bias power (V_{bias}) pulse is applied to the base electrode for a time duration (t_{bias}) that ranges between time t₂ (when the bias power is turned “on”) and the time t₃ (when the bias power is turned “off”). In some embodiments, the RF modulated bias power (V_{bias}) pulse may be turned “on” for approximately 65-85 μsec during the late afterglow phase (τ_{off}) of the pulsed plasma 150 to tune the flux of the ions extracted from the pulsed plasma 150. In one example implementation, a 500 W RF modulated bias power (V_{bias}) pulse may be applied for approximately 75 μsec after a 20 μsec time delay (t_{delay}). However, one skilled in the art would understand how alternative predetermined time delays, bias power levels and/or pulse durations may be utilized to tune the flux of the ions extracted from the pulsed plasma 150.

The ion flux of the pulsed plasma 150 is modulated by applying a bias power pulse in the late afterglow phase of the pulsed plasma (i.e., after the predetermined time delay). As known in the art, ions have two different velocities, including a thermal velocity (which propagates roughly in the x-direction) and an ion velocity (which propagates roughly in the y-direction). Once the source power is turned “off” (at time t₁) and the pulsed plasma 150 generated within the process chamber 105 fully quenches (sometime between time t₁ and time t₂), the ions generated within the plasma have little to no thermal velocity in the x-direction. However, the ion velocity in the y-direction is maintained during the afterglow phase (τ_{off}) of the pulsed plasma 150 and determined by the bias power applied to the base electrode. By applying an RF modulated bias power (V_{bias}) pulse in the late afterglow phase (τ_{off}) of the pulsed plasma 150 after the predetermined time delay (t_{delay}), highly directional positive and negative ions can be extracted from the ion-ion sheath 157 and accelerated towards the substrate. This improves the anisotropic etch profiles of features etched within material layers formed on the substrate 110, compared to conventional etch processes that utilize CW plasmas.

As shown in FIG. 2, modulating the source power (V_{source}) pulse with an RF modulation frequency (e.g., 0.1-10 kHz) changes the polarity of the source power (V_{source}) applied during each pulse period (e.g., 100-10,000 μsec) of the RF modulation frequency. In some embodiments, the RF source power (V_{source}) pulse applied to the RF antenna 125 may be modulated at a lower modulation frequency (e.g., 100 Hz) to modulate the radical flux of the pulsed plasma 150 generated within the process chamber 105. As known in the art, radical flux modulation may affect the etch profile of the features etched within the material layers formed on the substrate 110. In other embodiments, however, a higher modulation frequency (e.g., 10 kHz) may be applied to the source power (V_{source}) pulse. Unlike lower modulation frequencies, higher modulation frequencies have little to no effect on the radical flux.

Like the RF modulation applied to the source power pulse, modulating the bias power (V_{bias}) pulse with an RF modulation frequency (e.g., 0.1-10 kHz) changes the polarity of the bias power (V_{bias}) applied during each pulse period (e.g., 100-10,000 μsec) of the RF modulation frequency. The RF modulation applied to the bias power (V_{bias}) pulse enables both positive ions and negative ions to be extracted from the ion-ion sheath 157 during the late afterglow phase of the pulsed plasma 150 (as shown in FIG. 3), which improves anisotropic etching of the features etched within the material layers formed on the substrate 110.

FIG. 3 illustrates a plasma etch process 300 that may be performed within the plasma processing system 100 shown in FIG. 1 to etch features (e.g., contact holes, vias, trenches, etc.) within one or more material layers formed on the substrate 110 using the RF modulated pulsed plasma scheme 200 shown in FIG. 2. As shown in FIG. 3, a plurality of layers may be formed on a base layer 305, such as for example, a semiconductor substrate. The plurality of layers may include, but are not limited to, one or more underlying layers 310 formed on the base layer 305, a dielectric layer 315 formed on top of the underlying layer(s) 310, and a hard mask layer 320 formed on top of the dielectric layer 315. Other layers may be included, as is known in the art.

In some embodiments, the hard mask layer 320 may be implemented with a metal hard mask material, such as but not limited to, a titanium-based, tungsten-based or ruthenium-based hard mask material. Specific examples of metal hard mask materials suitable for use herein may include, but are not limited to, titanium nitride (TiN), tungsten carbide (WC), tungsten nitride (WN), tungsten silicide (WSix), ruthenium nitride (RuN), ruthenium Silicide (RuSi), etc. In some embodiments, the hard mask layer 320 may be deposited to a thickness ranging between 15 nm to 18 nm. In some embodiments, the dielectric layer 315 may be a low-k dielectric layer, such as SiOCH and SiCOOH, and the one or more underlying layers 310 may include aluminum oxide (Al₂O₃). The base layer 305 may be a silicon substrate.

In the plasma etch process step 330 shown in FIG. 3, a feature 325 is etched within the hard mask layer 320 by applying an RF modulated source power (V_{source}) pulse, as shown in FIG. 2, to the RF antenna 125 shown in FIG. 1, while process gases are supplied to the process chamber 105. As noted above, the process gases supplied to the process chamber 105 may include a wide variety of electronegative gases (such as, e.g., halogen-containing gases, fluorocarbons and oxygen-containing gases) and inert gases (such as argon). When an RF modulated source power (V_{source}) pulse is applied in the plasma etch process step 330, a high-frequency inductive electric field is generated, which dissociates and converts the process gases delivered to the process chamber 105 into a pulsed plasma 150. During the active glow phase (τₒₙ) when the RF modulated source power (V_{source}) pulse is turned “on”, positive ions are extracted from the plasma sheath 155 and accelerated towards the substrate 110 (e.g., roughly in the y-direction) to etch the feature 325 within the hard mask layer 320.

In the plasma etch process step 340 shown in FIG. 3, an RF modulated bias power (V_{bias}) pulse is applied to the base electrode during the late afterglow phase (τ_{off}) of the pulsed plasma 150. As shown in FIG. 2, the RF modulated bias power (V_{bias}) pulse is applied after a predetermined time delay (t_{delay}), which allows the plasma generated within the process chamber 105 to fully quench. As shown in FIG. 3, application of the RF modulated bias power (V_{bias}) pulse in the late afterglow phase enables positive ions and negative ions to be alternately extracted from the ion-ion sheath 157 and accelerated towards the substrate 110 (e.g., roughly in the y-direction) to etch the feature 325 within the hard mask layer 320. The plasma etch process steps 330 and 340 shown in FIG. 3 represent one pulse period (τₚ) of the pulsed plasma scheme 200 shown in FIG. 2, and thus, may be repeated for a number of cycles needed to etch the feature 325 within the hard mask layer 320.

As shown in FIGS. 2 and 3, combining RF modulated source pulsing with RF modulated bias pulsing in the late afterglow phase results in the acceleration of positive ions out of the plasma sheath 155 (during the active glow phase) and alternating acceleration of positive and negative ions out of the ion-ion sheath 157 (during the afterglow phase) onto the substrate 110. Since the flux of the bombarding ions is anisotropic (substantially perpendicular to the substrate 110 and parallel to the electric field), and since the energy of the ions can be tuned by controlling the bias, the positive ions extracted from the plasma sheath 155 (during the active glow phase) and the positive and negative ions alternately extracted from the ion-ion sheath 157 (during the late afterglow phase) can be utilized to provide highly anisotropic etch profiles of the features 325 etched within hard mask layer 320.

As noted above and illustrated in FIG. 3, the flux of the bombarding ions is described as being anisotropic, substantially perpendicular to the substrate 110 and/or roughly in the y-direction. Due to field imperfections and other factors, however, the bombarding ions may not necessarily strike the substrate surface with normal incidence, but typically exhibit some range of incidence angles around normal. In some embodiments, the positive ions extracted from the plasma sheath 155 (during the active glow phase) and the positive and negative ions extracted from the ion-ion sheath 157 (during the afterglow phase) may bombard a surface of the substrate at an angle of incidence. This angle of incidence may fall, for example, within +/−10° of perpendicular (or normal) to the substrate surface.

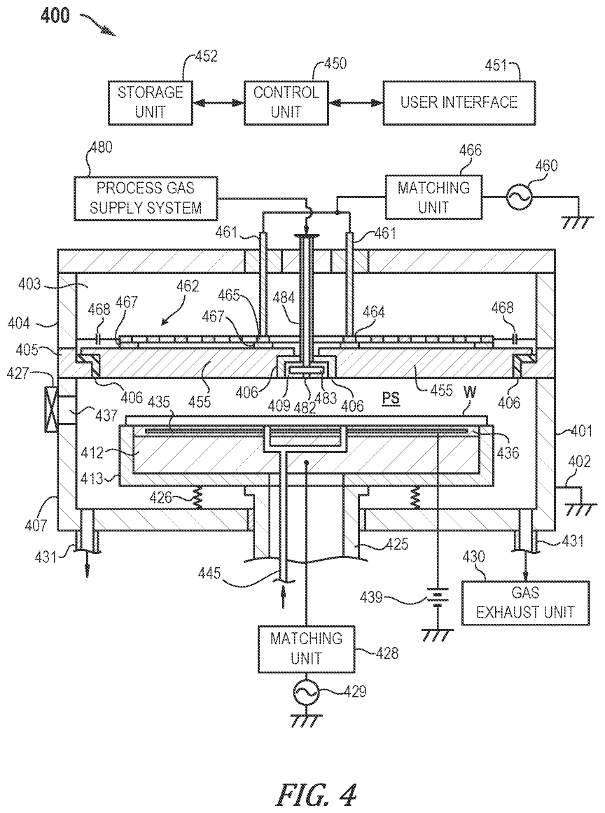

FIG. 4 illustrates one example processing system 400 that may be used to perform the techniques described herein. The processing system 400 shown in FIG. 4 is an inductively coupled plasma (ICP) processing tool. It will be recognized that the processing system 400 shown in FIG. 4 is merely one example of an ICP processing tool and a wide range of other inductively coupled plasma processing tools may be utilized to perform the techniques described herein. It is further recognized that the techniques described herein are not limited to an inductively coupled plasma processing system and other plasma processing systems may also be utilized.

This processing system 400 shown in FIG. 4 can be used for multiple operations including plasma ashing, deposition, etching and sputtering. Plasma processing can be executed within processing chamber 401, which can be a vacuum chamber made of a metal such as aluminum or stainless steel. The processing chamber 401 is grounded such as by ground wire 402. The processing chamber 401 defines a processing vessel providing a process space (PS) for plasma generation. An inner wall of the processing vessel can be coated with alumina, yttria, or other protectant. The processing vessel can be cylindrical, square, column-shaped, etc.

At a lower central area within the processing chamber 401, a susceptor 412 can serve as a mounting table on which, for example, a substrate W to be processed (such as a semiconductor wafer) can be mounted. The substrate W can be moved into the processing chamber 401 through loading/unloading port 437 and gate valve 427. The susceptor 412 (which can be disc-shaped) can be made of a conductive material. An electrostatic chuck 436 is provided on the susceptor 412 for holding the substrate W. The electrostatic chuck 436 is provided with an electrode 435. Electrode 435 is electrically connected to DC power source 439 (direct current power source). The electrostatic chuck 436 attracts the substrate W thereto via an electrostatic force generated when DC voltage from the DC power source 439 is applied to the electrode 435 so that substrate W is securely mounted on the susceptor 412. The susceptor 412 can include an insulating frame 413 and be supported by support 425, which can include an elevation mechanism. The susceptor 412 can be vertically moved by the elevation mechanism during loading and/or unloading of the substrate W. A bellows 426 can be disposed between the insulating frame 413 and a bottom portion of the processing chamber 401 to surround support 425 as an airtight enclosure. Susceptor 412 can include a temperature sensor and a temperature control mechanism including a coolant flow path, a heating unit such as a ceramic heater or the like (all not shown) that can be used to control a temperature of the substrate W. A focus ring (not shown) can be provided on an upper surface of the susceptor 412 to surround the electrostatic chuck 436 and assist with directional ion bombardment.

A gas supply line 445, which passes through the susceptor 412, may be configured to supply heat transfer gas to an upper surface of the electrostatic chuck 436. A heat transfer gas (also known as backside gas) such as helium (He) can be supplied between the substrate W and the electrostatic chuck 436 via the gas supply line 445 to assist in heating the substrate W.

A gas exhaust unit 430 including a vacuum pump and the like can be connected to a bottom portion of the processing chamber 401 through gas exhaust line 431. The gas exhaust unit 430 can include a vacuum pump such as a turbo molecular pump configured to decompress the plasma processing space within the processing chamber 401 to a desired vacuum condition during a given plasma processing operation.

As shown in FIG. 4, the processing system 400 can be partitioned into an antenna chamber 403 and a processing chamber 401 by a window 455. The window 455 can be implemented with a dielectric material, such as quartz, or a conductive material, such as metal. In the embodiments in which the window 455 is implemented with a metal material, the window 455 can be electrically insulated from the processing chamber 401, such as with insulators 406. In the example processing system 400 shown in FIG. 4, the window 455 forms a ceiling of the processing chamber 401. In some embodiments, the window 455 can be divided into multiple sections, which may optionally be insulated from each other.

Provided between the sidewall 404 of the antenna chamber 403 and the sidewall 407 of the processing chamber 401 is a support shelf 405 projecting toward the inside of the processing apparatus. A support member 409 serves to support the window 455 and also functions as a shower housing for supplying a processing gas to the process space (PS). When the support member 409 serves as the shower housing, a gas channel 483, extending in a direction parallel to a working surface of a substrate W to be processed, is formed inside the support member 409 and communicates with gas injection openings 482 for injecting process gas into the process space (PS). A gas supply line 484 in communication with the gas channel 483 defines a flow path through the ceiling of the processing chamber 401, and is connected to a process gas supply system 480, which may include a processing gas supply source, a valve system and corresponding components. Accordingly, during plasma processing, a given process gas can be injected into the process space (PS).

A high-frequency antenna 462 (e.g., a radio frequency antenna) is disposed within the antenna chamber 403 above the window 455 so as to face the window 455. In some embodiments, the high-frequency antenna 462 can be spaced apart from the window 455 by a spacer 467 made of an insulating material. The high-frequency antenna 462 can be formed in a spiral shape or formed in other configurations.

During plasma processing, a high frequency power having a frequency of, e.g., 27 MHz (or another frequency), can be supplied from a first high-frequency power source 460 to the high-frequency antenna 462 via power feed members 461 for generating an inductive electric field, which may be used to disassociate and convert the process gases supplied to the processing chamber 401 into a plasma. An impedance matching unit 466 can be connected to the first high-frequency power source 460. The high-frequency antenna 462 in this example can have corresponding power feed portion 464 and power feed portion 465 connected to the power feed members 461, as well as additional power feed portions depending on a particular antenna configuration. Power feed portions can be arranged at similar diametrical distances and angular spacing. Antenna lines can extend outwardly from power feed portion 464 and power feed portion 465 (or inwardly depending on antenna configuration) to an end portion of antenna lines. End portions of antenna lines are connected to the capacitors 468, and the antenna lines are grounded via the capacitors 468. Capacitors 468 can include one or more variable capacitors.

With a given substrate W is mounted within the processing chamber 401, one or more plasma processing operations can be executed. By applying high frequency power to the high-frequency antenna 462, an inductive electric field is generated in the processing chamber 401, and processing gas supplied from the gas injection openings 482 is turned into a plasma by the inductive electric field. The plasma can then be used to process a given substrate such as by etching, ashing, deposition, etc.

A second high-frequency power source 429 is connected to the susceptor 412 via a matching unit 428. The second high-frequency power source 429 supplies a high frequency bias power having a frequency of, e.g., 13 MHz (or another frequency), to the mounting table (or base electrode) during plasma processing. Applying high frequency bias power causes ions, in the plasma generated in the processing chamber 401, to be attracted to the substrate W.

Components of the processing system 400 can be connected to, and controlled by, a control unit 450, which in turn can be connected to a corresponding storage unit 452 and user interface 451. Various plasma processing operations can be executed via the user interface 451, and various plasma processing recipes and operations can be stored in storage unit 452. Accordingly, a given substrate W can be processed within the processing chamber 401 with various microfabrication techniques.

The techniques described herein for etching features (e.g., contact holes, vias, trenches, etc.) within one or more material layers formed on the substrate W may be accomplished with a variety of etch process conditions (such as power, pressure, temperature, gasses, flow rates, etc.). An exemplary process recipe is described herein for etching features within a metal hard mask material using an inductively coupled plasma processing system; however other process tools, process conditions, materials and variables may be utilized.

In one embodiment, the processing system 400 shown in FIG. 4 may be used to etch a feature 325 within a hard mask layer 320 formed above a dielectric layer 315, as shown in FIG. 3 and described above. As noted above, the hard mask layer 320 may include a wide variety of metal hard mask materials, including but not limited to, titanium-based, tungsten-based or ruthenium-based hard mask materials, and may be deposited to a thickness ranging between 15 nm to 18 nm.

In some embodiments, a plasma etch process 300 as shown in FIG. 3 may be performed within the processing system 400 using the pulsed plasma scheme 200 shown in FIG. 2 to etch the feature 325 within the hard mask layer 320. For example, the plasma etch process 300 shown in FIG. 3 may etch the feature 325 within the hard mask layer 320 using a 100-300 W source power (V_{source}) pulse having a driving frequency ranging between about 13 MHz to 60 MHz, a 100-500 W bias power (V_{bias}) pulse having a driving frequency ranging between about 1 MHz to 13 MHz, a chamber pressure in a range of 10-30 mTorr, and a temperature in a range of 20-70 degrees Celsius. Gasses utilized in the plasma etch process 300 may include, but are not limited to, argon (Ar) in a range of 100-300 standard cubic centimeters per minute (sccm), chlorine (Cl₂) in a range of 50-200 sccm, oxygen (O₂) in a range of 0-50 sccm, nitrogen trifluoride (NF₃) in a range of 15-350 sccm and methane (CH₄) in a range of 0-20 sccm. Other halogen-containing gases, oxygen-containing gases, fluorocarbons and/or inert gases may also be utilized, as is known in the art.

As noted above, the source power (V_{source}) pulse and the bias power (V_{bias}) pulse may be modulated with an RF modulation frequency ranging between 0.1-10 kHz. The pulse duration of the source power (V_{source}) pulse and the bias power (V_{bias}) pulse may each last between 10-50% of the pulse period. The duration of the source power (V_{source}) pulse is a control knob, which may be used to control the plasma density of the pulsed plasma. The duration of the bias power (V_{bias}) pulse is another control knob, which may be used to tune the flux of the ions extracted from the pulsed plasma. For example, the duration of the bias power (V_{bias}) pulse may be adjusted depending on the bias power level, the process gases supplied to the processing chamber 401, the thickness of the target material layers, the pitch of the features to be etched within the target material layers, the RF modulation frequency and other etch process conditions.

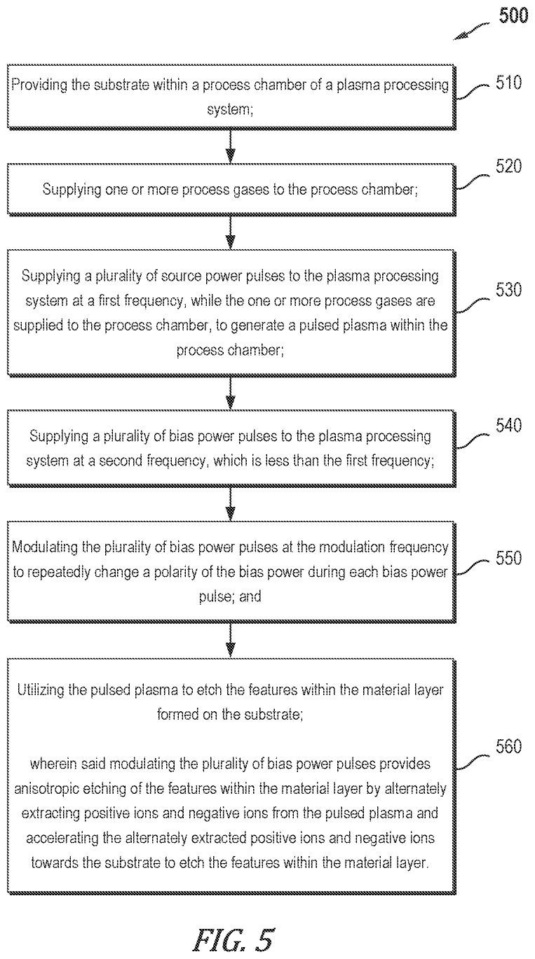

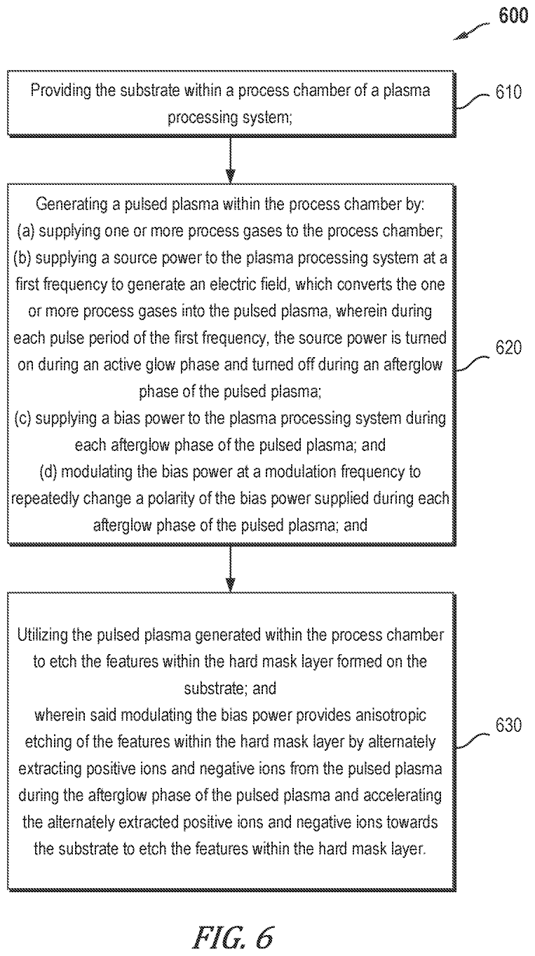

FIGS. 5 and 6 illustrate embodiments of exemplary methods that utilize the techniques described herein to improve anisotropic etching of material layers formed on a substrate, such as but not limited to, metal hard mask layers formed over dielectric layers. It will be recognized that the embodiments shown in FIGS. 5 and 6 are merely exemplary and additional methods may utilize the techniques described herein. Further, additional processing steps may be added to the method shown in FIGS. 5 and 6 as the steps described are not intended to be exclusive. Moreover, the order of the steps is not limited to the order shown in the figure as different orders may occur and/or various steps may be performed in combination or at the same time.

FIG. 5 is a flowchart diagram illustrating one embodiment of a method 500 that utilizes the techniques described herein to improve anisotropic etching of features etched within a material layer formed on a substrate. As shown in FIG. 5, the method 500 may generally include providing the substrate within a process chamber of a plasma processing system (in step 510); supplying one or more process gases to the process chamber (in step 520); supplying a plurality of source power pulses to the plasma processing system at a first frequency, while the one or more process gases are supplied to the process chamber, to generate a pulsed plasma within the process chamber (in step 530); supplying a plurality of bias power pulses to the plasma processing system at a second frequency, which is less than the first frequency (in step 540); modulating the plurality of bias power pulses at the modulation frequency to repeatedly change a polarity of the bias power during each bias power pulse (in step 550); and utilizing the pulsed plasma to etch the features within the material layer formed on the substrate (in step 560). In the method 500 shown in FIG. 5, modulating the plurality of bias power pulses in step 550 provides anisotropic etching of the features within the material layer by alternately extracting positive ions and negative ions from the pulsed plasma and accelerating the alternately extracted positive ions and negative ions towards the substrate to etch the features within the material layer. In some embodiments, the alternately extracted positive ions and negative ions may bombard a surface of the substrate at an angle of incidence that is within 10 degrees of perpendicular to the substrate.

The method 500 shown in FIG. 5 may be utilized within a wide variety of plasma processing systems. In some embodiments, the method 500 may be utilized within an inductively coupled plasma (ICP) processing system. In such embodiments, supplying the plurality of source power pulses in step 530 may include supplying the plurality of source power pulses to a radio frequency (RF) antenna included within an ICP processing system to generate an inductive electric field, which converts the one or more process gases supplied to the process chamber into the pulsed plasma. In addition, supplying the plurality of bias power pulses in step 540 may include supplying the plurality of bias power pulses to a base electrode included within the ICP processing system. In some embodiments, the one or more process gases supplied to the process chamber in step 520 may include at least one halogen-containing gas.

In some embodiments, the plurality of source power pulses may be supplied at a source power level ranging between 100 W and 300 W, the first frequency may range between 13 MHz to 60 MHz. In some embodiments, the method 500 may further include modulating the plurality of source power pulses at the modulation frequency to repeatedly change a polarity of the source power during each source power pulse. In such embodiments, the modulation frequency may range between 100 Hz to 10 kHz. In one example embodiment, 300 W source power pulses may be supplied in step 530 at a first frequency of 27 MHz, and the source power pulses may be modulated at a modulation frequency of 10 kHz.

In some embodiments, the plurality of bias power pulses may be supplied at a bias power level ranging between 100 W and 500 W, the second frequency may range between 1 MHz to 13 MHz, and the modulation frequency may range between 100 Hz to 10 kHz. In one example embodiment, 500 W bias power pulses may be supplied in step 540 at a second frequency of 13 MHz, and the bias power pulses may be modulated in step 550 at a modulation frequency of 10 kHz.

In some embodiments, the method 500 may further include providing a predetermined time delay between each source power pulse supplied to the RF antenna and each bias power pulse supplied to the base electrode. As noted above, the predetermined time delay enables the pulsed plasma generated within the process chamber to fully quench before each bias power pulse is supplied to the base electrode. In some embodiments, the predetermined time delay may range between 15-30 μsec. In one example implementation, the predetermined time delay may be 20 μsec.

The method 500 shown in FIG. 5 may be utilized for etching a wide variety of material layers. In some embodiments, the method 500 may be utilized for etching features within a metal hard mask layer overlying a dielectric layer. In one example, the metal hard mask layer may include titanium, tungsten or ruthenium hard mask materials, and the dielectric layer may include a low-k dielectric material.

FIG. 6 is a flowchart diagram illustrating another embodiment of a method 600 that utilizes the techniques described herein to provide anisotropic etching of features within a hard mask layer formed on a substrate. As shown in FIG. 6, the method 600 may include providing the substrate within a process chamber of a plasma processing system (in step 610), generating a pulsed plasma within the process chamber (in step 620) and utilizing the pulsed plasma generated within the process chamber to etch the features within the hard mask layer formed on the substrate (in step 630).

More specifically, the method 600 shown in FIG. 6 may generate a pulsed plasma within the process chamber (in step 620) by: (a) supplying one or more process gases to the process chamber; (b) supplying a source power to the plasma processing system at a first frequency to generate an electric field, which converts the one or more process gases into the pulsed plasma, wherein during each pulse period of the first frequency, the source power is turned on during an active glow phase and turned off during an afterglow phase of the pulsed plasma; (c) supplying a bias power to the plasma processing system during each afterglow phase of the pulsed plasma; and (d) modulating the bias power at a modulation frequency to repeatedly change a polarity of the bias power supplied during each afterglow phase of the pulsed plasma. In some embodiments, said supplying the bias power in step (c) may include turning the bias power on a predetermined time delay after the source power is turned off during each afterglow phase of the pulsed plasma. As noted above, the predetermined time delay enables the pulsed plasma generated within the process chamber to fully quench before the bias power pulse is turned on.

Modulating the bias power in step (d) alternately extracts positive ions and negative ions from the pulsed plasma during the afterglow phase of the pulsed plasma and provides anisotropic etching of the features within the hard mask layer (in step 630) by accelerating the alternately extracted positive ions and negative ions towards the substrate to etch the features within the hard mask layer. In some embodiments, the alternately extracted positive ions and negative ions may bombard a surface of the substrate at an angle of incidence that is within 10 degrees of perpendicular to the substrate.

In some embodiments, the method 600 may further include modulating the source power at the modulation frequency to repeatedly change a polarity of the source power supplied during each active glow phase of the pulsed plasma. Modulating the source power extracts positive ions from the pulsed plasma during the active glow phase of the pulsed plasma, and improves anisotropic etching of the features within the hard mask layer (in step 630) by accelerating the positive ions extracted during the active glow phase towards the substrate to etch the features within the hard mask layer. In some embodiments, the positive ions may bombard a surface of the substrate at an angle of incidence that is within 10 degrees of perpendicular to the substrate.

Like the method 500 shown in FIG. 5, the method 600 shown in FIG. 6 may be utilized within a wide variety of plasma processing systems. In some embodiments, the method 600 may be utilized within an inductively coupled plasma (ICP) processing system. In such embodiments, supplying the source power in step 620 may include supplying the source power pulses to a radio frequency (RF) antenna included within an ICP processing system to generate an inductive electric field, which converts the one or more process gases supplied to the process chamber into the pulsed plasma. In addition, supplying the bias power in step 620 may include supplying the bias power to a base electrode included within the ICP processing system at a second frequency range, which is less than the first frequency range. In some embodiments, the one or more process gases supplied to the process chamber may include at least one halogen-containing gas.

In some embodiments, the source power may be supplied at a source power level ranging between 100 W and 300 W, the first frequency may range between 13 MHz to 60 MHz, and the modulation frequency may range between 100 Hz to 10 kHz. In one example embodiment, 300 W of source power may be supplied at a first frequency of 27 MHz and modulated at a modulation frequency of 10 kHz in step 620.

In some embodiments, the bias power may be supplied at a bias power level ranging between 100 W and 500 W, the second frequency may range between 1 MHz to 13 MHz, and the modulation frequency may range between 100 Hz to 10 kHz. In one example embodiment, 500 W of bias power may be supplied at a second frequency of 13 MHz and modulated at a modulation frequency of 10 kHz in step 620.

The method 600 shown in FIG. 6 may also be utilized for etching a wide variety of hard mask layers. In some embodiments, the method 600 may be utilized for etching features within a metal hard mask layer overlying a dielectric layer. In one example, the metal hard mask layer may include titanium, tungsten or ruthenium hard mask materials, and the dielectric layer may include a low-k dielectric material.

Plasma processing systems, plasma etch process steps and methods for etching metal hard mask materials using an RF modulated plasma pulse scheme are described herein in various embodiments. TABLE 1 summarizes the improvements observed from using a pulsed plasma scheme as described herein compared to a conventional continuous (CW) process. More specifically, TABLE 1 summarizes data obtained during an exemplary process where a titanium nitride (TiN) hardmask with an overlying tetraethyl orthosilicate (TEOS) layer was etched at a pressure of 30 mTorr using the pulsed plasma process described herein and a conventional CW process. The source power and bias power used in the CW process were 300 W and 100 W, respectively.

For the pulsed process, the source power (300 W) delivered to the plasma was modulated at 10 kHz (100 μs period). The active glow commences at t=0 μs, and the source power was turned off at t=20 μs (i.e., a duty cycle of 20%). Unlike the pulsed plasma scheme 200 shown in FIG. 2 and described above, RF modulated bias power was applied to the base electrode during the entire pulse period (τₚ) in the pulsed process summarized in TABLE 1. Specifically, a 50 W bias power was applied during two separate periods of time in one cycle: 0-40 μs and 60-100 μs, and a 500 W bias power was applied from 40 to 60 μs into the afterglow, lasting for 20 μs. Like the source power, the bias power applied to the base electrode was modulated at 10 kHz (100 μs period) in the pulsed process.

TABLE 1

| Parameter | CW process [nm] | Pulsed process [nm] | Improvement [%] |
|---|---|---|---|
| Undercut | 1.8 | 0.6 | 66 |
| Bow | 0.8 | 0.5 | 38 |
| Taper | 1.5 | 0.3 | 80 |

Undercut was measured (in nm) as the difference between the bottom critical dimension (CD) of the TEOS layer overlying the TiN hardmask, and the top CD of the TiN hardmask. Bow was measured (in nm) as the difference between the top and middle CDs of the TiN hardmask layer, and taper was measured (in nm) as the difference between the bottom and top CDs of the TiN hardmask layer. As is evidenced by the data presented in TABLE 1, significant improvements of all three metrics (e.g., 66% improvement in undercut, 38% improvement in bow and 80% improvement in taper) were achieved by using the pulsed plasma scheme described herein over the continuous (CW) process.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate including a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

Further modifications and alternative embodiments of the described plasma processing systems, plasm process steps and methods will be apparent to those skilled in the art in view of this description. It will be recognized, therefore, that the described systems and methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method for etching features within a material layer formed on a substrate, the method comprising:
providing the substrate within a process chamber of a plasma processing system;
supplying one or more process gases to the process chamber;
supplying a plurality of source power pulses to the plasma processing system at a first frequency, while the one or more process gases are supplied to the process chamber, to generate a pulsed plasma within the process chamber;
supplying a plurality of bias power pulses to the plasma processing system at a second frequency, which is less than the first frequency;
modulating the plurality of bias power pulses at a modulation frequency to repeatedly change a polarity of the bias power during each bias power pulse; and
utilizing the pulsed plasma to etch the features within the material layer formed on the substrate;
wherein said modulating the plurality of bias power pulses provides anisotropic etching of the features within the material layer by alternately extracting positive ions and negative ions from the pulsed plasma and accelerating the alternately extracted positive ions and negative ions towards the substrate to etch the features within the material layer.

2. The method of claim 1, wherein said supplying one or more process gases to the process chamber comprising supplying at least one halogen-containing gas to the process chamber.

3. The method of claim 1, wherein said supplying the plurality of source power pulses comprises supplying the plurality of source power pulses to a radio frequency (RF) antenna included within an inductively coupled plasma (ICP) processing system to generate an inductive electric field, which converts the one or more process gases supplied to the process chamber into the pulsed plasma.

4. The method of claim 3, wherein the plurality of source power pulses are supplied at a source power level ranging between 100 W and 300 W, and wherein the first frequency ranges between 13 MHz to 60 MHz.

5. The method of claim 3, further comprising modulating the plurality of source power pulses at the modulation frequency to repeatedly change a polarity of the source power during each source power pulse, wherein the modulation frequency ranges between 100 Hz to 10 kHz.

6. The method of claim 3, wherein said supplying the plurality of bias power pulses comprises supplying the plurality of bias power pulses to a base electrode included within the ICP processing system.

7. The method of claim 6, wherein the plurality of bias power pulses are supplied at a bias power level ranging between 100 W and 500 W, wherein the second frequency ranges between 1 MHz to 13 MHz, and wherein the modulation frequency ranges between 100 Hz to 10 kHz.

8. The method of claim 6, further comprising providing a predetermined time delay between each source power pulse supplied to the RF antenna and each bias power pulse supplied to the base electrode, wherein the predetermined time delay enables the pulsed plasma generated within the process chamber to fully quench before each bias power pulse is supplied to the base electrode.

9. The method of claim 1, wherein said utilizing the pulsed plasma to etch the features within the material layer formed on the substrate comprises utilizing the pulsed plasma to etch the features within a metal hard mask layer overlying a dielectric layer.

10. The method of claim 9, wherein the metal hard mask layer comprises titanium, tungsten or ruthenium hard mask materials, and wherein the dielectric layer comprises a low-k dielectric material.

11. The method of claim 1, wherein the alternately extracted positive ions and negative ions bombard a surface of the substrate at an angle of incidence that is within 10 degrees of perpendicular to the substrate.

12. A method to provide anisotropic etching of features within a hard mask layer formed on a substrate, the method comprising:
providing the substrate within a process chamber of a plasma processing system;
generating a pulsed plasma within the process chamber by:
supplying one or more process gases to the process chamber;
supplying a source power to the plasma processing system at a first frequency to generate an electric field, which converts the one or more process gases into the pulsed plasma, wherein during each pulse period of the first frequency, the source power is turned on during an active glow phase and turned off during an afterglow phase of the pulsed plasma;
supplying a bias power to the plasma processing system during each afterglow phase of the pulsed plasma; and
modulating the bias power at a modulation frequency to repeatedly change a polarity of the bias power supplied during each afterglow phase of the pulsed plasma; and
utilizing the pulsed plasma generated within the process chamber to etch the features within the hard mask layer formed on the substrate; and
wherein said modulating the bias power provides anisotropic etching of the features within the hard mask layer by alternately extracting positive ions and negative ions from the pulsed plasma during the afterglow phase of the pulsed plasma and accelerating the alternately extracted positive ions and negative ions towards the substrate to etch the features within the hard mask layer.

13. The method of claim 12, wherein during each afterglow phase of the pulsed plasma, said supplying the bias power comprises turning the bias power on a predetermined time delay after the source power is turned off, wherein the predetermined time delay enables the pulsed plasma generated within the process chamber to fully quench before the bias power is turned on.

14. The method of claim 12, further comprising modulating the source power at the modulation frequency to repeatedly change a polarity of the source power supplied during each active glow phase of the pulsed plasma, wherein said modulating the source power provides anisotropic etching of the features within the hard mask layer by extracting positive ions from the pulsed plasma during the active glow phase of the pulsed plasma and accelerating the positive ions towards the substrate to etch the features within the hard mask layer.

15. The method of claim 12, wherein said supplying one or more process gases to the process chamber comprising supplying at least one halogen-containing gas to the process chamber.

16. The method of claim 12, wherein said supplying the source power comprises supplying the source power to a radio frequency (RF) antenna included within an inductively coupled plasma (ICP) processing system to generate an inductive electric field, which converts the one or more process gases supplied to the process chamber into the pulsed plasma.

17. The method of claim 16, wherein the source power is supplied at a source power level ranging between 100 W and 300 W, and wherein the first frequency ranges between 13 MHz to 60 MHz.

18. The method of claim 17, further comprising modulating the source power at the modulation frequency to repeatedly change a polarity of the source power supplied during each active glow phase of the pulsed plasma, and wherein the modulation frequency ranges between 100 Hz to 10 kHz.

19. The method of claim 16, wherein said supplying the bias power comprises supplying the bias power to a base electrode included within the ICP processing system at a second frequency range.

20. The method of claim 19, wherein the bias power is supplied at a bias power level ranging between 100 W and 500 W, wherein the second frequency ranges between 1 MHz to 13 MHz, and the modulation frequency ranges between 100 Hz to 10 kHz.

21. The method of claim 12, wherein said utilizing the pulsed plasma to etch the features within the hard mask layer formed on the substrate comprises utilizing the pulsed plasma to etch the features within a metal hard mask layer overlying a dielectric layer.

22. The method of claim 21, wherein the metal hard mask layer comprises titanium, tungsten or ruthenium hard mask materials, and wherein the dielectric layer comprises a low-k dielectric material.

23. The method of claim 12, wherein the alternately extracted positive ions and negative ions bombard a surface of the substrate at an angle of incidence that is within 10 degrees of perpendicular to the substrate.
